(19) United States
(12) Patent Application Publication
(10) Pub. No.: US 2024/0379490 A1
(43) Pub. Date: Nov. 14, 2024

(54) FLIP-CHIP PACKAGE HEAT SPREADER

(71) Applicant: Tektronix, Inc., Beaverton, OR (US)

(72) Inventor: Kevin Bain Cox, Portland, OR (US)

(73) Assignee: Tektronix, Inc., Beaverton, OR (US)

(21) Appl. No.: 18/652,527

(22) Filed: May 1, 2024

Related U.S. Application Data
(60) Provisional application No. 63/464,884, filed on May 8, 2023.

(51) Int. Cl. H01L 23/367

(52) U.S. Cl. CPC H01L 23/3675

(57) ABSTRACT

A heat spreader may include a body having a first surface and a second surface opposite the first surface. Also, the heat spreader may include a wall disposed along a perimeter of the body, the wall extending from the first surface, the wall having a plurality of cut-outs. Furthermore, the heat spreader may include at least one channel extending from a first edge of the body to a second edge of the body parallel to the first edge, where the at least one channel disposed in a first cut-out of a first side of the wall and in a second cut-out of a second side of the wall opposite the first side.

### RELATED APPLICATIONS

This application claims the benefit of U.S. Provisional Patent No. 63/464,884, titled “RUGGEDIZED FLIP-CHIP PACKAGE HEAT SPREADER OPTIMIZED FOR ENVIRONMENTAL SURVIVAL,” filed May 8, 2023, which is incorporated herein in its entirety.

### TECHNICAL FIELD

This disclosure relates to semiconductor device packaging, and more particularly to a heat spreader for a flip-chip package.

### BACKGROUND

Achieving device reliability is a challenging requirement when an integrated circuit package is subjected to large thermal loads and a high number of cycles. A heat spreader component can be disposed on an integrated circuit die. The heat spreader component can serve several functionalities but also can introduce significant stresses on critical interfaces and lead to premature electrical failures. Therefore, design optimization of the heat spreader component is necessary to improve reliability and meet device requirements.

### SUMMARY

Examples of the present disclosure generally relate to a heat spreader component for a flip-chip package.

One example of the present disclosure is a heat spreader. The heat spreader may include a body having a first surface and a second surface opposite the first surface. The heat spreader may also include a plurality of pillars extending from the first surface, the plurality of pillars disposed along a perimeter of the body, each of the plurality of pillars having a longer side adjacent to the perimeter. The heat spreader may furthermore include at least one channel disposed between a pair of the plurality of pillars and separates the pair of the plurality of pillars.

One example of the present disclosure is a lid. The lid may include a body having a first surface and a second surface opposite the first surface. The lid may also include a wall disposed along a perimeter of the body, the wall extending from the first surface, the wall having a plurality of cut-outs. The lid may furthermore include at least one channel extending from a first edge of the body to a second edge of the body parallel to the first edge, where the at least one channel disposed in a first cut-out of a first side of the wall and in a second cut-out of a second side of the wall opposite the first side.

Another example of the present disclosure is an assembly may include a substrate. The assembly may also include a first die coupled with the substrate. The assembly may furthermore include a heat spreader thermally coupled with the substrate and the first die, the heat spreader having: a body with a first surface and a second surface opposite the first surface; and a plurality of pillars extending from the second surface toward the substrate, each pillar having a first end coupled to the body and a second end thermally coupled to the substrate, where each pillar is disposed adjacent to an edge of the body of the heat spreader, where one side of the pillar is coplanar to the edge of the body, where a channel separates at least one pair of pillars of the plurality of pillars.

### BRIEF DESCRIPTION OF DRAWINGS

So that the manner in which the above recited features can be understood in detail, a more particular description, briefly summarized above, may be had by reference to example implementations, some of which are illustrated in the appended drawings. It is to be noted, however, that the appended drawings illustrate only typical example implementations and are therefore not to be considered limiting of its scope.

FIG. 1 illustrates an example of the heat spreader described herein, and a close-up of the example heat spreader, according to some examples.

FIG. 2 is a bottom view of an example heat spreader, according to some examples.

FIG. 3 is a cross-sectional view of the heat spreader of FIG. 2, according to some examples.

FIG. 4 is a top view of an example substrate with example integrated circuit dies coupled to the substrate, according to some examples.

FIG. 5 shows both the bottom view of the example heat spreader of FIG. 2 and the cross-sectional view of the heat spreader of FIG. 3, according to some examples.

### DETAILED DESCRIPTION

Various features are described hereinafter with reference to the figures. It should be noted that the figures may or may not be drawn to scale and that the elements of similar structures or functions are represented by like reference numerals throughout the figures. It should be noted that the figures are only intended to facilitate the description of the features. They are not intended as an exhaustive description of the features or as a limitation on the scope of the claims. In addition, an illustrated example need not have all the aspects or advantages shown. An aspect or an advantage described in conjunction with a particular example is not necessarily limited to that example and can be practiced in any other examples even if not so illustrated, or if not so explicitly described.

Examples herein describe a heat spreader component for an integrated circuit (IC) package. The heat spreader disclosed herein uses a material optimized for matching the thermal expansion coefficient of the IC package. The heat spreader disclosed herein uses pillars, which are formed from removing sections of a perimeter wall of the heat spreader, which results in a more pliant component and leads to reduction of critical package stresses. The heat spreader disclosed herein uses channels to reduce heat spreader stiffness, which leads to further reduction of critical package stresses.

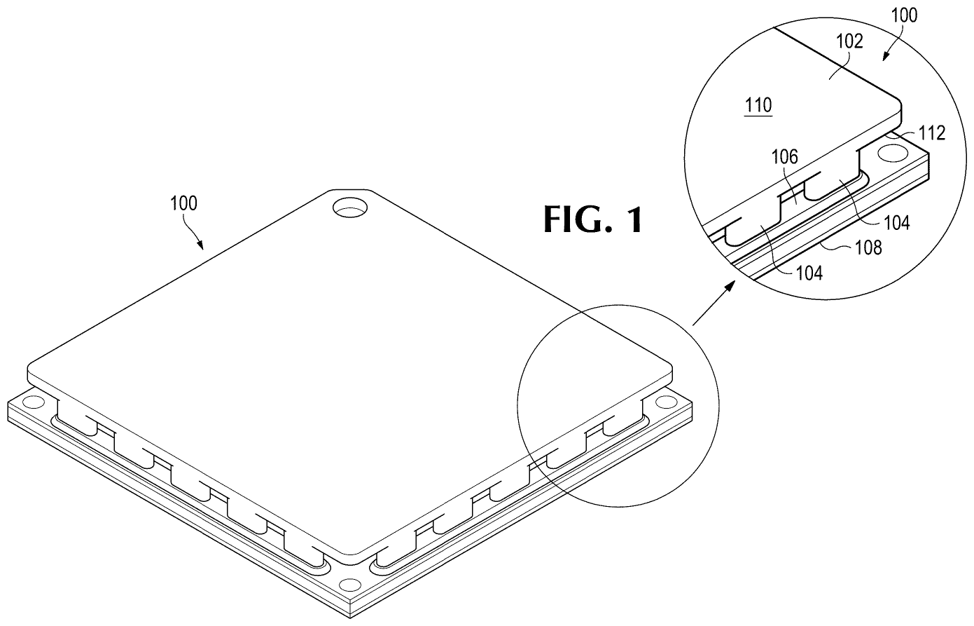

FIG. 1 illustrates an example of the heat spreader described herein, and a close-up of the example heat spreader, according to some examples. The heat spreader 100 comprises a body 102, pillars 104, and channels (not illustrated in FIG. 1). The heat spreader 100 is designed to contact a substrate 108, and in some examples, the heat spreader 100 is thermally coupled to the substrate 108. In some examples, the heat spreader 100 is thermally coupled to the substrate 108 directly or by thermal interface materials, including but not limited to curable adhesives, thermal greases, phase change materials, tapes, conductive sheets, solders, and sintered metals. In some examples, the heat spreader 100 can be a lid thermally coupled to IC dies (not illustrated) and to the substrate 108.

As illustrated in FIG. 1, the body 102 of the heat spreader 100 has a first surface 110 and a second surface 112. The second surface 112 is opposite the first surface 110 of the body 102 of the heat spreader 100, and in some examples, the second surface 112 faces the top surface of the substrate 108. The pillars 104 of the heat spreader 100 extend from the second surface 112 of the body 102 of the heat spreader 100. In some examples, the pillars 104 extend from the second surface 112 of the body 102 towards the top surface of the substrate 108. While the heat spreader 100 is described herein with reference to a flip-chip package, the heat spreader 100 can be used with any type of IC package according to the examples described herein.

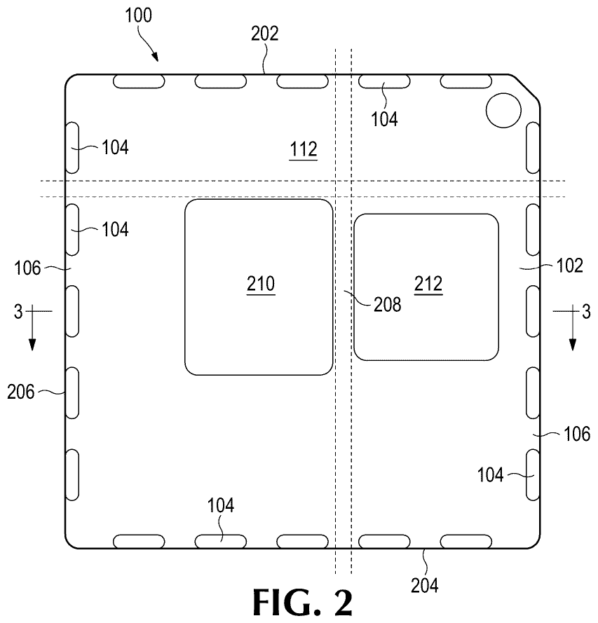

A channel 208 (illustrated in FIG. 2) is disposed between pillars 104 extending from the body 102 of the heat spreader 100. Further details about the channel are disclosed herein.

FIG. 2 is a bottom view of an example heat spreader, according to some examples. As mentioned, the heat spreader 100 included a body 102, pillars 104, and a channel 208, and as illustrated in FIG. 2, the pillars 104 are disposed along the perimeter of the body 102 of the heat spreader 100 and the channel 208 is disposed along the second surface 112 of the body 102 between pillars 104.

As mentioned, the heat spreader 100 disclosed herein uses pillars 104, which result in a more pliant component and leads to further reduction of critical package stresses. In some examples, the pillars 104 are formed by removing sections of a perimeter wall 206 of the heat spreader 100. In such examples, the perimeter wall 206 extends from the second surface 112 of the heat spreader 100 and abuts the perimeter of the heat spreader 100. Accordingly, removing sections of the perimeter wall 206 to form pillars 104 retains the functionality of the perimeter wall 206 and also allows for flexibility in the heat spreader 100 while allowing the pillars 104 to maintain thermal contact and/or electrical contact with the substrate 108. The pillars 104 can be formed by other techniques other than removing portions of the perimeter wall 206. The pillars 104 can have any size or shape and are arranged such that a long side of each pillar 104 is coplanar with and adjacent to an edge of the body 102 of the heat spreader 100, as illustrated in FIG. 1. The number of pillars 104 of the perimeter wall 206 can vary based on the removed sections of the perimeter wall, and the size, shape, and arrangement of pillars 104 can vary to reduce heat spreader stiffness and critical package stresses.

Removing sections of the perimeter wall 206 can introduce gaps 106 between pillars 104. The gaps 106 along with the pillars 104 allow for the heat spreader 100 to contract or expand based on the material of the heat spreader 100. The gaps 106 can have any width, and the height of the gaps 106 correspond with the height of the pillars 104 without the body 102. For example, at least one gap can have a gap width of 1.6 mm and a gap height of 1.25 mm, which is also the same height as the pillars 104. In some examples, each pillar 104 of the heat spreader 100 has the same height, and each gap 106 has the same height as the pillars 104. Also, the gaps 106 between the pillars 104 of the heat spreader 100 facilitates processing (fluid flow) through the wash line as the package is cleaned. Improved processability increases yield and can also improve package reliability. In some examples, the gaps 106 between the pillars 104 can be selectively filled with a filler material that can contract or expand as needed to reduce package stress. The filler material disposed between the gaps 106 may be more pliant than the material of the heat spreader 100 in order to maintain the stress reduction benefits while also closing the gaps 106 if the gaps 106 present any concerns for other package requirements.

The heat spreader 100 includes any number of channels 208. In some examples, a channel 208 is disposed in a gap 106, and as such, is disposed between pillars 104 of the perimeter wall 206. As illustrated, the channel 208 is disposed between pillars 104 on a first side 202 of the heat spreader 100 and pillars 104 on a second side 204 of the heat spreader 100. Accordingly, the channel 208 can extend the length of the heat spreader 100 from one side 202 to an opposite side 204 of the heat spreader 100. In some examples, the channel 208 can extend partially across the second surface 112 of the heat spreader 100. The channel 208 can have any width to accommodate the size of the pillars 104 and the spacing between the pillars 104. In some examples, the channel 208 on the second surface 112 of the heat spreader 100 can create one or more pedestals 210, 212 to which IC dies (not illustrated in FIG. 2) are coupled. Accordingly, the width of the channel 208 depends on the distance between the IC dies. The channel 208 can also reduce the stiffness of the heat spreader 100, which thereby leads to further reduction of critical package stresses.

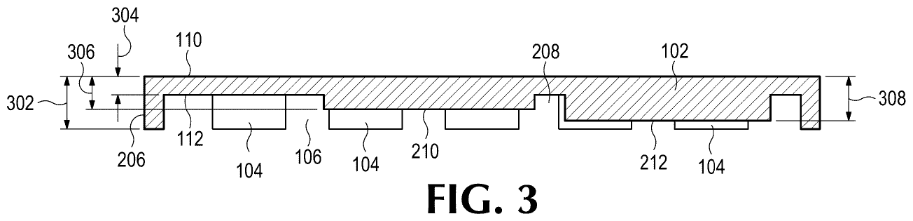

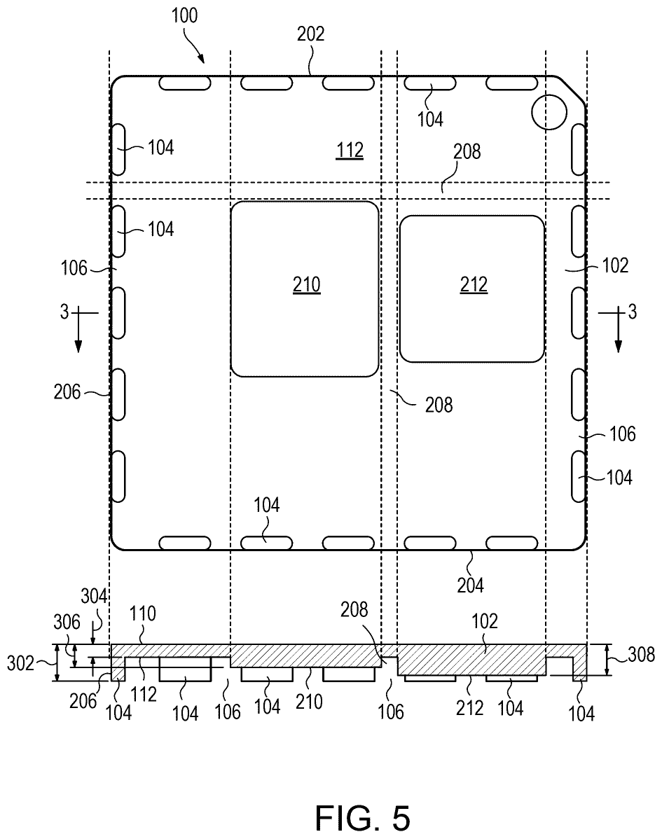

FIG. 3 is a cross-sectional view of the heat spreader 100 of FIG. 2, according to some examples. The cross-sectional view of the heat spreader 100 of FIG. 3 is taken along the line 3-3 in FIG. 2, and illustrates the pedestals 210, 212 of the heat spreader 100. FIG. 5 shows both the bottom view of the example heat spreader of FIG. 2 and the cross-sectional view of the heat spreader of FIG. 3, according to some examples.

As illustrated in FIG. 3 and FIG. 5, the pedestals 210, 212 of the heat spreader 100 are coupled to the body 102 of the heat spreader 100. In some examples, the pedestals 210, 212 are a part of the body 102 of the heat spreader 100. The body 102 of the heat spreader 100 has a thickness 304, and because the pedestals 210, 212 are coupled to the body 102 of the heat spreader 100, the pedestal 210 has thickness 306 and the pedestal 212 has thickness 308, both of which include thickness 304 of the body 102 of the heat spreader 100. As mentioned, when the heat spreader 100 is coupled to the substrate 108 and to IC dies, the pedestals 210, 212 are thermally coupled to the IC dies. Accordingly, the thickness 306, 308 of the pedestals 210, 212 can depend on the height of the IC dies coupled to the substrate 108. In some examples, the pedestals 210, 212 is thermally coupled to the IC dies directly or by thermal interface materials, including but not limited to curable adhesives, thermal greases, phase change materials, tapes, conductive sheets, solders, and sintered metals. Furthermore, as illustrated, the thickness 306, 308 of the pedestals 210, 212 is less than the height 302 of the heat spreader 100, which includes the height of the pillars 104 and the body 102. The heat spreader 100 can have any number of pedestals 210, 212, and the heat spreader 100 can have any arrangement of the pedestals 210, 212 on the second surface 112 of the heat spreader 100. In some examples, the number and arrangement of pedestals 210, 212 depends on the number and arrangement of IC dies on the substrate 108. The IC dies can have any size or shape, and accordingly, the pedestals 210, 212 are sized and shaped according to the size and/or shape of the IC dies.

In some examples, the channel 208 of the heat spreader 100 is disposed between pedestals 210, 212, varying the thickness of the heat spreader 100 and thereby reducing stiffness of the heat spreader 100 across the pedestals 210, 212. The heat spreader 100 can include any number, orientation, and arrangement of channels disposed adjacent to the pedestals 210, 212. In some examples, the channels can intersect each other, and the channels can be disposed between any two pillars 104 of the heat spreader 100.

The heat spreader 100 may be formed from a thermally conductive material optimized for matching the package thermal expansion coefficient. The thermally conductive material used for the heat spreader 100 depends on the stiffness (e.g., thicknesses, materials, moduli), geometries of the IC dies, interconnects, solder bumps, and interposer, and device exposure temperatures. As mentioned, the heat spreader 100 is thermally coupled to IC dies and is designed to transfer the heat of the IC dies to the heat spreader 100. Accordingly, the material of the heat spreader 100 is formed from a thermally conductive material for transferring the heat from the IC dies. In some examples, the thermally conductive material of the heat spreader 100 includes copper molybdenum, copper tungsten, or other combinations. In some examples, the heat spreader 100 is formed from multiple thermally conductive materials, and in such examples, the different thermally conductive materials for the heat spreader 100 are arranged according to the IC dies coupled to the substrate 108. The material of the heat spreader 100 provides the benefit of reduced stresses in critical regions by improving package warpage.

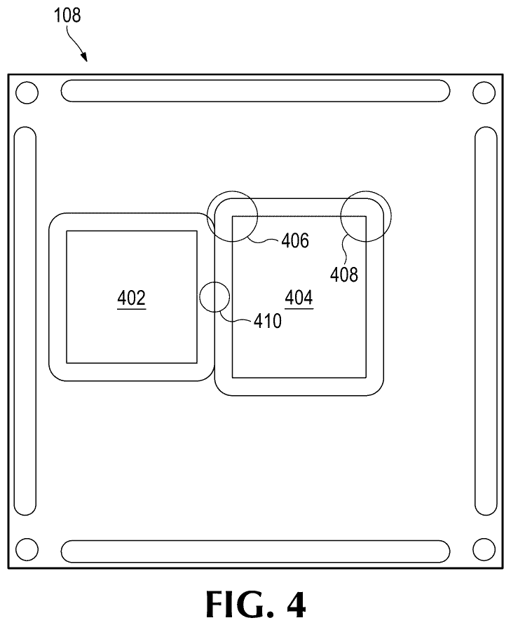

FIG. 4 is a top view of an example substrate with example IC dies coupled to the substrate, according to some examples. As illustrated, IC dies 402, 404 are disposed on the substrate 108. Because of the proximity of the IC dies 402, 404 to each other, increased stress because of heat occurs at regions 406, 408, and 410, which can lead to warpage and delamination. Accordingly, the heat spreader 100 as described herein, when coupled to the substrate 108, can reduce the stress at regions 406, 408, and 410 in a packaged component as described herein. For example, the pedestals 210, 212 are coupled to dies 402, 404, and channel 208 between the pedestals 210, 212 can facilitate the reduction of stress at regions 406, 410.

### EXAMPLES

Illustrative examples of the disclosed technologies are provided below. An embodiment of the technologies may include one or more, and any combination of, the examples described below.

Example 1 is a heat spreader comprising a body having a first surface and a second surface opposite the first surface. The heat spreader includes a plurality of pillars extending from the first surface, the plurality of pillars disposed along a perimeter of the body, each of the plurality of pillars having a longer side adjacent to the perimeter. The heat spreader includes at least one channel disposed between a pair of the plurality of pillars and separates the pair of the plurality of pillars.

Example 2 is the heat spreader of Example 1, wherein the body comprises a first portion and a second portion, wherein the first portion comprises a first thickness and the second portion comprises a second thickness.

Example 3 is the heat spreader of Example 1, wherein each of the plurality of pillars has a uniform thickness.

Example 4 is the heat spreader of Example 1, wherein the body comprises a thermally conductive material.

Example 5 is the heat spreader of Example 1, wherein the at least one channel extends from one edge of the body to another edge of the body.

Example 6 is the heat spreader of Example 1, wherein the plurality of pillars comprises: a first set of pillars, each having a side coplanar to a first edge of the body; a second set of pillars, each having a side coplanar to a second edge of the body, the second edge parallel to the first edge of the body; a third set of pillars, each having a side coplanar to a third edge of the body, the third edge perpendicular to the first edge of the body and the second edge of the body; and a fourth set of pillars, each having a side coplanar to a fourth edge of the body, the fourth edge perpendicular to the first edge of the body and the second edge of the body and parallel to the third edge of the body.

Example 7 is the heat spreader of Example 1, wherein at least one of the plurality of pillars has only one side adjacent to the perimeter of the body.

Example 8 is a lid comprising a body having a first surface and a second surface opposite the first surface. The lid includes a wall disposed along a perimeter of the body, the wall extending from the first surface, the wall comprising a plurality of cut-outs. The lid includes at least one channel extending from a first edge of the body to a second edge of the body parallel to the first edge, wherein the at least one channel disposed in a first cut-out of a first side of the wall and in a second cut-out of a second side of the wall opposite the first side.

Example 9 is the lid of Example 8, wherein the body comprises a first portion and a second portion, wherein the first portion comprises a first thickness and the second portion comprises a second thickness.

Example 10 is the lid of Example 9, wherein the at least one channel is adjacent to the second portion of the body.

Example 11 is the lid of Example 8, wherein the body comprises a thermally conductive material.

Example 12 is the lid of Example 8, wherein the wall comprises at least one perimeter portion, the perimeter portion formed by a first cut-out and a second cut-out of the plurality of cut-outs.

Example 13 is the lid of Example 12, wherein only one side of the at least one perimeter portion is adjacent to the perimeter of the body.

Example 14 is the lid of Example 8, wherein the wall comprises: a first portion; a second portion parallel to the first portion; a third portion perpendicular to the first portion and the second portion; and a fourth portion perpendicular to the first portion and the second portion and parallel to the third portion.

Example 15 is the lid of Example 8, wherein each channel has a uniform width.

Example 16 is an assembly comprising a substrate, a die coupled with the substrate, and a heat spreader thermally coupled with the substrate and the die. The heat spreader includes a body with a first surface and a second surface opposite the first surface. The heat spreader includes a plurality of pillars extending from the second surface toward the substrate, each pillar having a first end coupled to the body and a second end thermally coupled to the substrate, wherein each pillar is disposed adjacent to an edge of the body of the heat spreader, wherein one side of the pillar is coplanar to the edge of the body, wherein a channel separates at least one pair of pillars of the plurality of pillars.

Example 17 is the assembly of Example 16, wherein the body comprises a first portion and a second portion, the second portion having a different thickness than the first portion, the second portion coupled to the die.

Example 18 is the assembly of Example 17, wherein the channel is adjacent to the second portion.

Example 19 is the assembly of Example 16, wherein the channel extends from a first edge of the body of the heat spreader to a second edge of the body of the heat spreader, the second edge parallel to the first edge.

Example 20 is the assembly of Example 16, wherein the plurality of pillars comprises: a first set of pillars, each having a side coplanar to a first edge of the body; a second set of pillars, each having a side coplanar to a second edge of the body, the second edge parallel to the first edge of the body; a third set of pillars, each having a side coplanar to a third edge of the body, the third edge perpendicular to the first edge of the body and the second edge of the body; and a fourth set of pillars, each having a side coplanar to a fourth edge of the body, the fourth edge perpendicular to the first edge of the body and the second edge of the body and parallel to the third edge of the body.

Additionally, this written description makes reference to particular features. It is to be understood that the disclosure in this specification includes all possible combinations of those particular features. Where a particular feature is disclosed in the context of a particular aspect or example, that feature can also be used, to the extent possible, in the context of other aspects and examples.

In this document, relational terms such as first and second, top and bottom, and the like may be used solely to distinguish one entity or action from another entity or action without necessarily requiring or implying any actual such relationship or order between such entities or actions. The terms “comprises,” “comprising,” “includes,” “including,” “has,” “having,” or any other variations thereof, are intended to cover a non-exclusive inclusion, such that a process, method, article, or apparatus that comprises a list of elements does not include only those elements but may include other elements not expressly listed or inherent to such process, method, article, or apparatus. An element preceded by “comprises . . . a” does not, without more constraints, preclude the existence of additional identical elements in the process, method, article, or apparatus that comprises the element.

Reference throughout this document to “one embodiment,” “certain embodiments,” “an embodiment,” “implementation(s),” “aspect(s),” or similar terms means that a particular feature, structure, or characteristic described in connection with the embodiment is included in at least one embodiment of the present disclosure. Thus, the appearances of such phrases or in various places throughout this specification are not necessarily all referring to the same embodiment. Furthermore, the particular features, structures, or characteristics may be combined in any suitable manner in one or more embodiments without limitation.

The term “or,” as used herein, is to be interpreted as an inclusive or meaning any one or any combination. Therefore, “A, B or C” means “any of the following: A, B; C; A and B; A and C; B and C; A, B and C.” An exception to this definition will occur only when a combination of elements, functions, steps or acts are in some way inherently mutually exclusive.

All features disclosed in the specification, including the claims, abstract, and drawings, and all the steps in any method or process disclosed, may be combined in any combination, except combinations where at least some of such features and/or steps are mutually exclusive. Each feature disclosed in the specification, including the claims, abstract, and drawings, can be replaced by alternative features serving the same, equivalent, or similar purpose, unless expressly stated otherwise.

Although specific examples of the invention have been illustrated and described for purposes of illustration, it will be understood that various modifications may be made without departing from the spirit and scope of the invention. Accordingly, the invention should not be limited except as by the appended claims.

1. A heat spreader comprising,
a body having a first surface and a second surface opposite the first surface;
a plurality of pillars extending from the first surface, the plurality of pillars disposed along a perimeter of the body, each of the plurality of pillars having a longer side adjacent to the perimeter; and
at least one channel disposed between a pair of the plurality of pillars and separates the pair of the plurality of pillars.

2. The heat spreader of claim 1, wherein the body comprises a first portion and a second portion, wherein the first portion comprises a first thickness and the second portion comprises a second thickness.

3. The heat spreader of claim 1, wherein each of the plurality of pillars has a uniform thickness.

4. The heat spreader of claim 1, wherein the body comprises a thermally conductive material.

5. The heat spreader of claim 1, wherein the at least one channel extends from one edge of the body to another edge of the body.

6. The heat spreader of claim 1, wherein the plurality of pillars comprises:
a first set of pillars, each having a side coplanar to a first edge of the body;
a second set of pillars, each having a side coplanar to a second edge of the body, the second edge parallel to the first edge of the body;
a third set of pillars, each having a side coplanar to a third edge of the body, the third edge perpendicular to the first edge of the body and the second edge of the body; and
a fourth set of pillars, each having a side coplanar to a fourth edge of the body, the fourth edge perpendicular to the first edge of the body and the second edge of the body and parallel to the third edge of the body.

7. The heat spreader of claim 1, wherein at least one of the plurality of pillars has only one side adjacent to the perimeter of the body.

8. A lid comprising,
a body having a first surface and a second surface opposite the first surface;
a wall disposed along a perimeter of the body, the wall extending from the first surface, the wall comprising a plurality of cut-outs; and
at least one channel extending from a first edge of the body to a second edge of the body parallel to the first edge, wherein the at least one channel disposed in a first cut-out of a first side of the wall and in a second cut-out of a second side of the wall opposite the first side.

9. The lid of claim 8, wherein the body comprises a first portion and a second portion, wherein the first portion comprises a first thickness and the second portion comprises a second thickness.

10. The lid of claim 9, wherein the at least one channel is adjacent to the second portion of the body.

11. The lid of claim 8, wherein the body comprises a thermally conductive material.

12. The lid of claim 8, wherein the wall comprises at least one perimeter portion, the perimeter portion formed by a first cut-out and a second cut-out of the plurality of cut-outs.

13. The lid of claim 12, wherein only one side of the at least one perimeter portion is adjacent to the perimeter of the body.

14. The lid of claim 8, wherein the wall comprises:
a first portion;
a second portion parallel to the first portion;
a third portion perpendicular to the first portion and the second portion; and
a fourth portion perpendicular to the first portion and the second portion and parallel to the third portion.

15. The lid of claim 8, wherein each channel has a uniform width.

16. An assembly, comprising:
a substrate;
a die coupled with the substrate; and
a heat spreader thermally coupled with the substrate and the die, the heat spreader comprising:
a body with a first surface and a second surface opposite the first surface; and
a plurality of pillars extending from the second surface toward the substrate, each pillar having a first end coupled to the body and a second end thermally coupled to the substrate, wherein each pillar is disposed adjacent to an edge of the body of the heat spreader, wherein one side of the pillar is coplanar to the edge of the body, wherein a channel separates at least one pair of pillars of the plurality of pillars.

17. The assembly of claim 16, wherein the body comprises a first portion and a second portion, the second portion having a different thickness than the first portion, the second portion coupled to the die.

18. The assembly of claim 17, wherein the channel is adjacent to the second portion.

19. The assembly of claim 16, wherein the channel extends from a first edge of the body of the heat spreader to a second edge of the body of the heat spreader, the second edge parallel to the first edge.

20. The assembly of claim 16, wherein the plurality of pillars comprises:
a first set of pillars, each having a side coplanar to a first edge of the body;
a second set of pillars, each having a side coplanar to a second edge of the body, the second edge parallel to the first edge of the body;
a third set of pillars, each having a side coplanar to a third edge of the body, the third edge perpendicular to the first edge of the body and the second edge of the body; and
a fourth set of pillars, each having a side coplanar to a fourth edge of the body, the fourth edge perpendicular to the first edge of the body and the second edge of the body and parallel to the third edge of the body.
